(19) United States
(12) Patent Application Publication
(10) Pub. No.: US 2023/0411360 A1
(43) Pub. Date: Dec. 21, 2023

(54) LIGHT-EMITTING DEVICE

(71) Applicant: NICHIA CORPORATION, Anan-shi (JP)

(72) Inventor: Soichiro MIURA, Tokushima-shi (JP)

(21) Appl. No.: 18/337,336

(22) Filed: Jun. 19, 2023

(30) Foreign Application Priority Data
Jun. 21, 2022 (JP) 2022-099818

(51) Int. Cl. H01L 25/075; H01L 33/50; H01L 33/10; H01L 33/62; H01L 33/56; H01L 33/48

(52) U.S. Cl. CPC H01L 25/075; H01L 33/502; H01L 33/10; H01L 33/62; H01L 33/56; H01L 33/483

(57) ABSTRACT

A light-emitting device includes, a base member having a placement surface, a light-emitting element disposed on the placement surface and configured to emit light from an emitting end surface, and a wavelength conversion member disposed on the placement surface along a direction in which the light emitted from the light-emitting element travels. The wavelength conversion member includes a wiring region that is a part of a current path electrically connected to the light-emitting element.

### CROSS-REFERENCE TO RELATED APPLICATION

This application claims priority to Japanese Patent Application No. 2022-099818, filed on Jun. 21, 2022, the disclosure of which is hereby incorporated herein by reference in its entirety.

### BACKGROUND

The present disclosure relates to a light-emitting device.

Japanese Patent Publication No. 2020-144363 discloses a light-emitting device in which light emitted from a plurality of semiconductor laser elements is reflected by a light reflective member and incident on a wavelength conversion portion, and the light incident on the wavelength conversion portion is converted into light having a different wavelength and emitted to the outside by the wavelength conversion portion. Laser light might cause blindness or other risks when being directly irradiated to the eye, but it is considered that the light emitted from the wavelength conversion portion is safe and free from such risks.

In consideration of safety, this light-emitting device takes a measure in case of cracks or other abnormalities in the wavelength conversion portion. Specifically, a conductive film is disposed around the wavelength conversion portion to detect abnormalities from a change in a resistance value of this conductive film. A current path that detects the abnormality and a current path through which power is supplied to the semiconductor laser element are provided in parallel.

### SUMMARY

The light emitting device described above can be indirectly controlled by checking for an abnormality in a light conversion portion, such as the wavelength conversion portion that converts laser light into safe light, and cutting off power supply to the semiconductor laser element when an abnormality is detected. However, a mechanism for directly cutting off the power supply to the semiconductor laser element due to an occurrence of the abnormality in the light conversion portion is not disclosed.

It is an object to provide a light-emitting device that directly stops power supply to a light-emitting element when an abnormality occurs in a light conversion portion.

A light-emitting device according to one embodiment of the present disclosure includes a base member, a light-emitting element, and a wavelength conversion member. The base member has a placement surface. The light-emitting element is disposed on the placement surface, and configured to emit first light from an emitting end surface. The wavelength conversion member is disposed at a portion of the placement surface to which the light emitted from the first light-emitting element travels. The wavelength conversion member has a wiring region being a part of a current path electrically connected to the light-emitting element. The wavelength conversion portion has an incident lateral surface on which the first light emitted from the light-emitting element is incident and an upper surface from which second light is emitted. The enclosing portion surrounds the wavelength conversion portion in a top view and provided with the wiring region.

A light-emitting device according to one embodiment of the present disclosure includes a base member, a light-emitting element, and a light conversion member. The base member has a placement surface. The light-emitting element is disposed on the placement surface, and configured to emit first light from an emitting end surface. The light conversion member is disposed at a portion of the placement surface to which the light emitted from the first light-emitting element travels. The light conversion member has a wiring region being a part of a current path electrically connected to the light-emitting element. The light conversion portion has an incident lateral surface on which the first light emitted from the light-emitting element is incident and an upper surface from which second light is emitted. The enclosing portion surrounds the light conversion portion in a top view and provided with the wiring region.

According to an embodiment of the present disclosure, a light-emitting device is provided in which a current path of the light-emitting element is cut off when an abnormality occurs in a wavelength conversion portion, thereby directly stopping power supply to a light-emitting element.

### BRIEF DESCRIPTION OF DRAWINGS

FIG. 1 is a schematic perspective view exemplifying a light-emitting device according to a first embodiment or a second embodiment.

FIG. 2 is a schematic perspective view of the light-emitting device according to the first embodiment, from which a lid portion is removed.

FIG. 3 is a schematic top view of the light-emitting device illustrated in FIG. 2.

FIG. 4 is a cross-sectional view of the light-emitting device according to the first embodiment taken along a cross-sectional line IV-IV in FIG. 1.

FIG. 5 is a schematic perspective view illustrating a structure example of a wavelength conversion portion according to the present disclosure.

FIG. 6 is a schematic perspective view illustrating a structure example of a wavelength conversion member according to the present disclosure.

FIG. 7 is a cross-sectional view of the wavelength conversion member taken along a cross-sectional line VII-VII in FIG. 6.

FIG. 8 is a schematic top view illustrating a current path of a light-emitting element in the light-emitting device according to the first embodiment.

FIG. 9 is a schematic top view of the light-emitting device according to the second embodiment, from which a lid portion is removed.

FIG. 10 is a cross-sectional view of the light-emitting device taken along a cross-sectional line X-X in FIG. 9.

FIG. 11 is a schematic top view of the light-emitting device illustrated in FIG. 9, from which members and wirings disposed on a placement surface of a base member are removed.

FIG. 12 is a schematic perspective view exemplifying a light-emitting device according to a third embodiment.

FIG. 13 is a schematic perspective view of the light-emitting device illustrated in FIG. 12, from which a frame portion and a lid portion are removed.

FIG. 14 is a schematic top view of the light-emitting device in the state illustrated in FIG. 13.

FIG. 15 is a cross-sectional view of the light-emitting device taken along a cross-sectional line XV-XV in FIG. 12.

### EMBODIMENTS

Hereinafter, an embodiment for carrying out the invention will be described with reference to the drawings. In the following description, terms indicating a specific direction or position (e.g., “upper”, “lower”, and other terms including or related to those terms) are used as necessary. The terms are used to describe a relative positional relationship to facilitate understanding of the invention with reference to the drawings, and thus fall within a technical scope of the present invention when relative positional relationships are substantially the same. In addition, parts having the same reference numerals or signs appearing in a plurality of drawings indicate identical or substantially equivalent parts or members.

In the present disclosure, polygons such as triangles and quadrangles, including shapes in which the corners of the polygon are rounded, chamfered, beveled, coved, and the like, are referred to as polygons. A shape obtained by processing not only the corners (ends of sides), but also an intermediate portion of a side is similarly referred to as a polygon. That is, a shape that is partially processed while leaving the polygonal shape as the base is included in the interpretation of the “polygon” described in the present disclosure.

The same applies not only to polygons but also to words representing specific shapes such as trapezoids, circles, protrusions, and recessions. Furthermore, the same applies to each side forming that shape. That is, even when processing is performed on a corner or an intermediate portion of a certain side, the processed portion is included as the interpretation of “side.” When a “polygon” or a “side” not partially processed is to be distinguished from a processed shape, “in a strict sense” will be added to the description as in, for example, “quadrangle in a strict sense.”

The following embodiments exemplify light-emitting devices and the like for embodying the technical concept of the present invention, and the present invention is not limited to the description below. The dimensions, materials, shapes, relative arrangements, and the like of constituent elements described below are not intended to limit the scope of the present invention to those alone, but are intended to provide an example, unless otherwise specified. The contents described in one embodiment can be applied to other embodiments and modification examples. The size, positional relationship, and the like of the members illustrated in the drawings can be exaggerated in order to clarify the explanation. To avoid excessive complication of the drawings, a schematic view in which some elements are not illustrated may be used, or a cross-sectional view or an end view may be used.

### First Embodiment

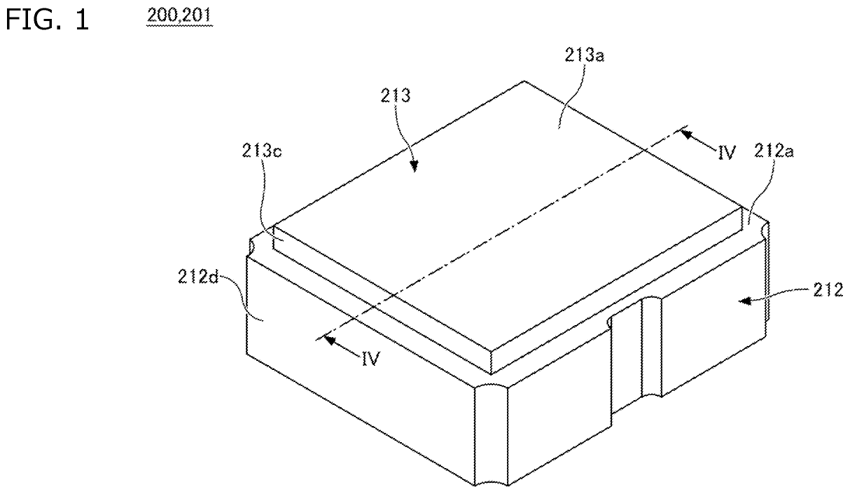

A light-emitting device according to a first embodiment includes a base member, a light-emitting element, and a wavelength conversion member. A structure example of a light-emitting device 200 according to the first embodiment will be described with reference to FIGS. 1 to 7.

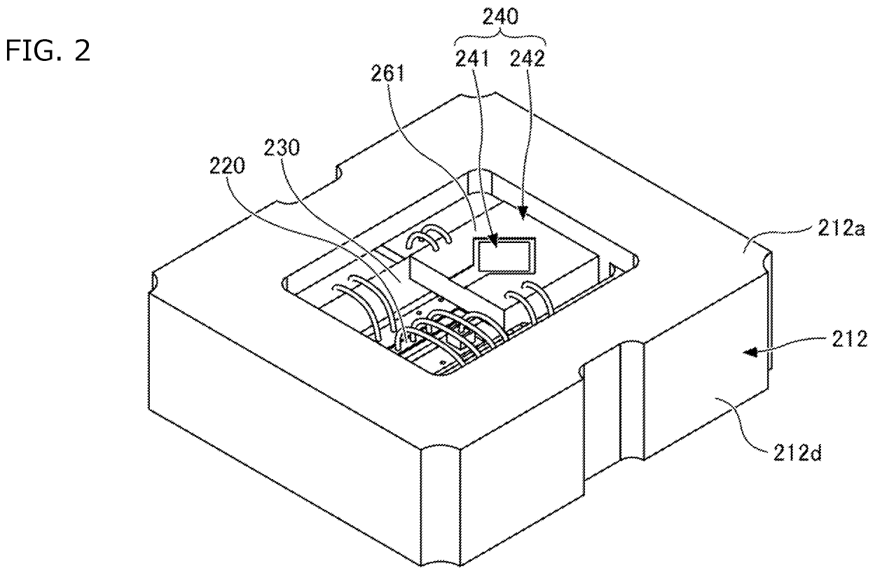

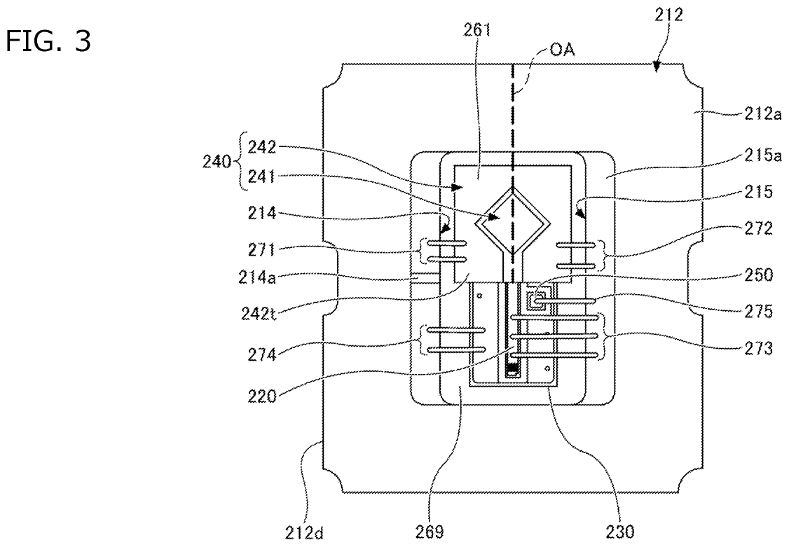

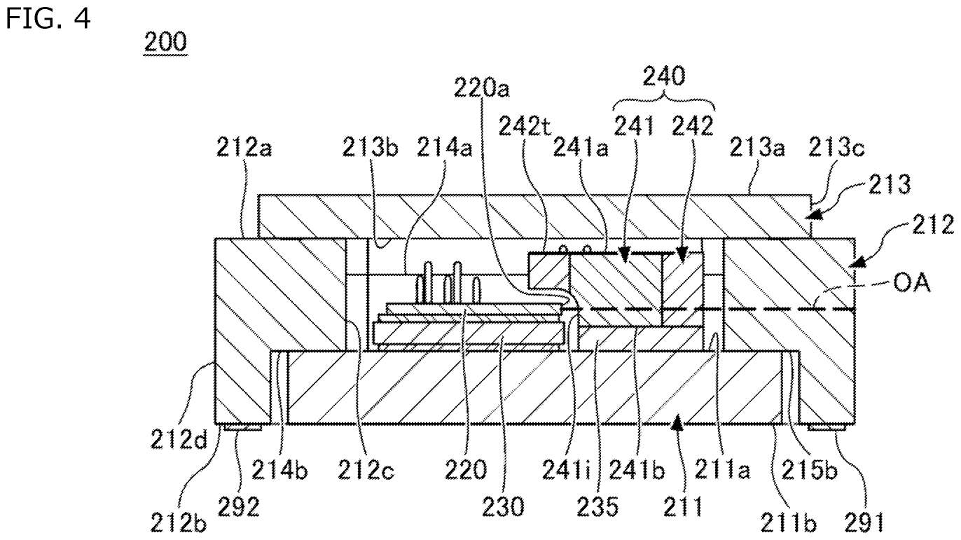

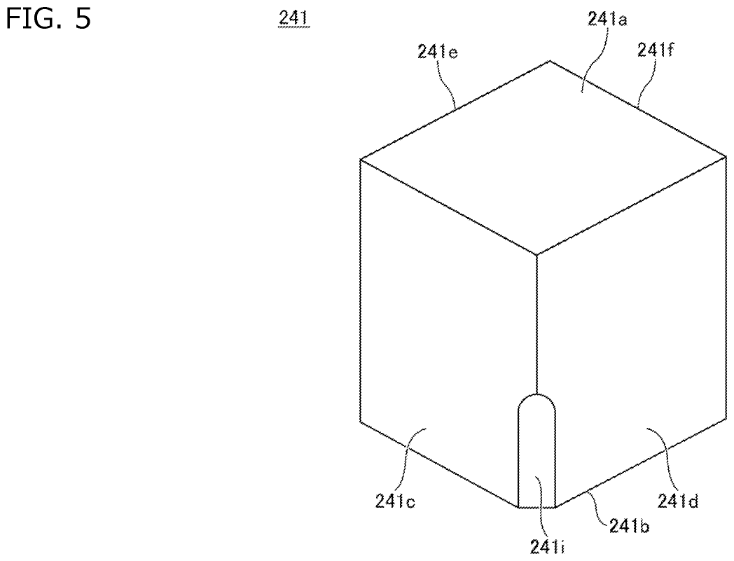

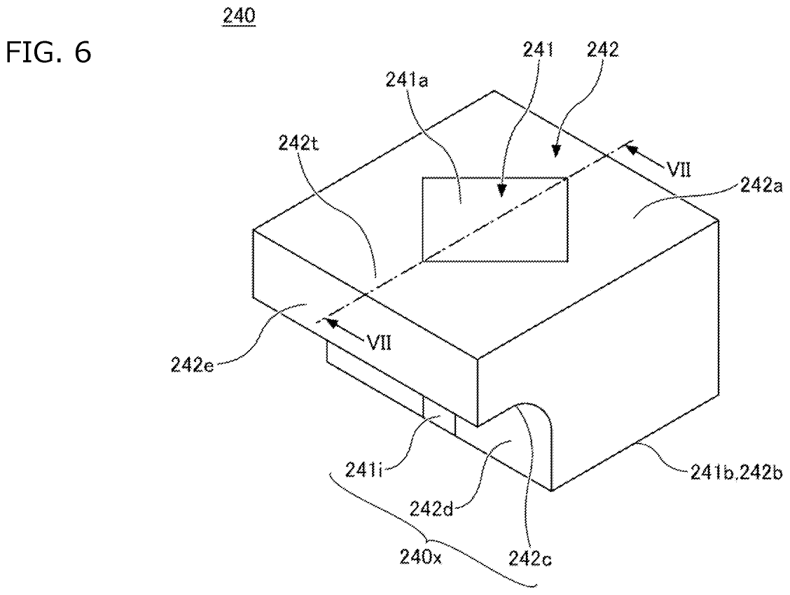

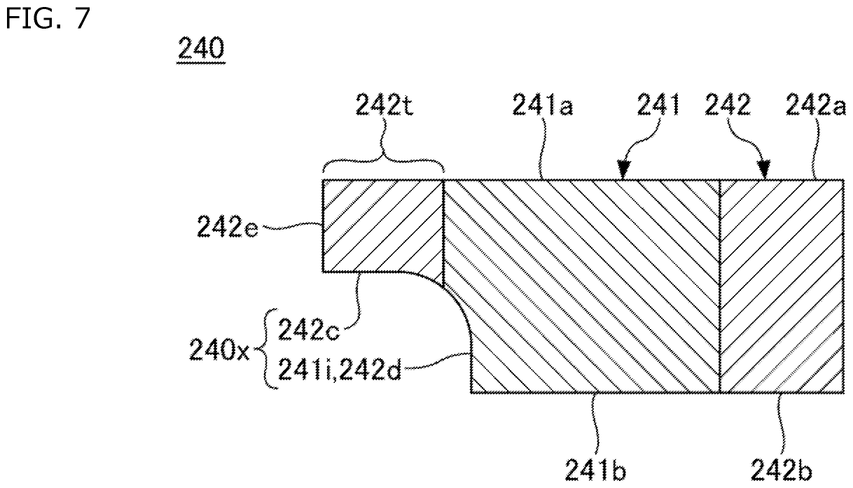

FIG. 1 is a schematic perspective view exemplifying the light-emitting device 200 according to the first embodiment. FIG. 2 is a schematic perspective view of the light-emitting device 200 illustrated in FIG. 1, from which a lid portion 213 is removed. FIG. 3 is a schematic top view of the light-emitting device 200 in the state illustrated in FIG. 2. FIG. 4 is a cross-sectional view of the light-emitting device 200 taken along a cross-sectional line IV-IV in FIG. 1. FIG. 5 is a schematic perspective view illustrating a structure example of a wavelength conversion portion 241 according to the present disclosure. FIG. 6 is a schematic perspective view illustrating a structure example of a wavelength conversion member 240 according to the present disclosure. FIG. 7 is a cross-sectional view of the wavelength conversion member 240 taken along a cross-sectional line VII-VII in FIG. 6.

The light-emitting device 200 according to the present embodiment includes a base member 210, one or a plurality of light-emitting elements 220, and the wavelength conversion member 240. In the illustrated example, the light-emitting device 200 further includes the lid portion 213, submounts 230 and 235, a protective element 250, and a first wiring 271 to a fifth wiring 275. The light-emitting device 200 may not include all of these components.

Each of the components of the light-emitting device 200 will be described.

### Base Member 210

The base member 210 has a bottom portion 211 and a frame portion 212. The base member 210 has a placement surface 211a. The bottom portion 211 has the placement surface 211a and a lower surface 211b. The bottom portion 211 has one or a plurality of lateral surfaces that join the placement surface 211a and the lower surface 211b. The one or the plurality of lateral surfaces join an outer edge of the placement surface 211a and an outer edge of the lower surface 211b. The base member 210 has the placement surface 211a and the lower surface 211b according to the definition described above.

The bottom portion 211 is, for example, a rectangular parallelepiped or a cube. In this case, both of the placement surface 211a and the lower surface 211b of the bottom portion 211 have a rectangular shape, and the bottom portion 211 has four lateral surfaces each having a rectangular shape. An outer shape of the bottom portion 211 in a top view may not be a rectangular shape. A rectangular shape may include a square shape unless specifically mentioned to exclude a square shape. Here, the top view refers to a view of an object from a normal line direction of the placement surface 211a of the bottom portion 211.

The bottom portion 211 can be formed of, for example, metal, ceramic, and the like as a main material. For example, aluminum, gold, silver, copper, tungsten, iron, nickel, cobalt, or an alloy thereof, or ceramic such as aluminum oxide, aluminum nitride, silicon nitride, and silicon carbide, diamond, a copper-diamond composite material, and the like can be used as a main material.

The frame portion 212 has an upper surface 212a, a lower surface 212b, one or a plurality of inner lateral surfaces 212c, and one or a plurality of outer lateral surfaces 212d. For example, the frame portion 212 has a rectangular ring-like shape in the top view. The one or the plurality of inner lateral surfaces 212c of the frame portion 212 are in contact with the placement surface 211a, and extend downward from the placement surface 211a. The one or the plurality of outer lateral surfaces 212d of the frame portion 212 are joined with the upper surface 212a and the lower surface 212b of the frame portion 212.

The frame portion 212 may further include a first stepped portion 214 having an upper surface 214a located above the placement surface 211a of the bottom portion 211 and below the upper surface 212a of the frame portion 212. Further, the frame portion 212 may further include a second stepped portion 215 having an upper surface 215a located above the placement surface 211a of the bottom portion 211 and below the upper surface 212a of the frame portion 212. The first stepped portion 214 and the second stepped portion 215 are provided inward of the frame portion 212. For example, the first stepped portion 214 is provided along an entire length of one side of an inner edge shape of the upper surface 212a of the frame portion 212. For example, the second stepped portion 215 is provided along an entire length of another side, of the inner edge shape of the upper surface 212a of the frame portion 212, this side facing the one side provided with the first stepped portion 214.

The first stepped portion 214 has, for example, the upper surface 214a and an inner lateral surface being joined with the upper surface 214a and extending downward. The upper surface 214a of the first stepped portion 214 is joined with the one or the plurality of inner lateral surfaces 212c of the frame portion 212. The upper surface 214a may be parallel to the placement surface 211a of the bottom portion 211. For example, the inner lateral surface of the first stepped portion 214 is in contact with the placement surface 211a of the bottom portion 211. The second stepped portion 215 has, for example, the upper surface 215a and an inner lateral surface being joined with the upper surface 215a and extending downward. The upper surface 215a of the second stepped portion 215 is joined with the one or the plurality of inner lateral surfaces 212c of the frame portion 212. The upper surface 215a may be parallel to the placement surface 211a of the bottom portion 211. For example, the inner lateral surface of the second stepped portion 215 is in contact with the placement surface 211a of the bottom portion 211. One or a plurality of conductive films may be provided at the upper surface 214a of the first stepped portion 214 and/or the upper surface 215a of the second stepped portion 215.

The first stepped portion 214 may further have a lower surface 214b joined with the inner lateral surface of the first stepped portion 214. The lower surface 214b is located below the upper surface 214a. The lower surface 214b may be a surface parallel to the upper surface 214a. The lower surface 214b is located above the lower surface 212b of the frame portion 212. The first stepped portion 214 may be provided such that the lower surface 214b is directly in contact with the placement surface 211a of the bottom portion 211, or may be provided such that the lower surface 214b is indirectly in contact with the placement surface 211a via a bonding member. In the example illustrated by the drawings, the frame portion 212 further has a lateral surface joined with the lower surface 214b and extending downward. This lateral surface is joined with the lower surface 212b of the frame portion 212.

The second stepped portion 215 may further have a lower surface 215b joined with the inner lateral surface of the second stepped portion 215. The lower surface 215b is located below the upper surface 215a. The lower surface 215b may be a surface parallel to the upper surface 215a. The lower surface 215b is located above the lower surface 212b of the frame portion 212. The second stepped portion 215 may be provided such that the lower surface 215b is directly in contact with the placement surface 211a of the bottom portion 211, or may be provided such that the lower surface 215b is indirectly in contact with the placement surface 211a via a bonding member. In the example illustrated by the drawings, the frame portion 212 further has a lateral surface joined with the lower surface 215b and extending downward. This lateral surface is joined with the lower surface 212b of the frame portion 212.

Furthermore, the frame portion 212 has one or a plurality of conductive films. The one or the plurality of conductive films (such as a third conductive film 263, a fourth conductive film 264, and/or a fifth conductive film 265 described below) can be provided at the upper surface 214a of the first stepped portion 214 and/or the upper surface 215a of the second stepped portion 215 of the frame portion 212. The one or the plurality of conductive films (such as a first external connection electrode 291 and/or a second external connection electrode 292 described below) can be provided at the lower surface 212b of the frame portion 212. the one or the plurality of conductive films may be provided at the upper surface 212a of the frame portion 212. The one or the plurality of conductive films provided at the upper surface 214a of the first stepped portion 214 and/or the upper surface 215a of the second stepped portion 215 may include a conductive film electrically connected to the conductive film provided at the upper surface 212a.

The base member 210 having the bottom portion 211 and the frame portion 212 forms a recessed shape recessed from the upper surface 212a of the frame portion 212 in a direction toward the placement surface 211a of the bottom portion 211. The recessed shape is formed inward of the frame portion 212 in the top view. In the top view, the placement surface 211a of the bottom portion 211 is surrounded by a frame formed by the one or the plurality of inner lateral surfaces 212c of the frame portion 212 and/or the inner lateral surfaces of the first stepped portion 214 and the second stepped portion 215. An outer shape of this frame is, for example, a rectangular shape having long sides and short sides. In the example illustrated by the drawings, the base member 210 is obtained by individually forming the bottom portion 211 and the frame portion 212 and bonding them together. The base member 210 may be monolithically formed.

The frame portion 212 can be formed of, for example, a material different from that of the bottom portion 211 as a main material. Examples of the main material forming the frame portion 212 include ceramic. For example, aluminum nitride, silicon nitride, aluminum oxide, or silicon carbide can be used as the ceramic. Further, other examples of the main material forming the frame portion 212 include iron, nickel, cobalt, or an alloy thereof, glass, or the like.

### Lid Portion 213

The lid portion 213 has an upper surface 213a and a lower surface 213b. The lid portion 213 has one or a plurality of lateral surfaces 213c in contact with the upper surface 213a and the lower surface 213b. The one or the plurality of lateral surfaces 213c join an outer edge of the upper surface 213a and an outer edge of the lower surface 213b. The lid portion 213 is, for example, a rectangular parallelepiped or a cube. In this case, both the upper surface 213a and the lower surface 213b of the lid portion 213 have a rectangular shape, and the lid portion 213 has four of the lateral surfaces 213c each having a rectangular shape.

However, the lid portion 213 is not limited to a rectangular parallelepiped or a cube. That is, the lid portion 213 is not limited to a rectangular shape in the top view, and can have any shape such as a circle, an oval, or a polygon.

The lid portion 213 is supported by the frame portion 212. The lid portion 213 is disposed above the placement surface 211a of the bottom portion 211. An outer peripheral portion of the lower surface 213b of the lid portion 213 is joined to the upper surface 212a of the frame portion 212, for example. By bonding the lid portion 213 to the frame portion 212, a sealed space surrounded by the bottom portion 211, the frame portion 212, and the lid portion 213 is formed.

The lid portion 213 may include a light transmitting region that transmits light having a predetermined wavelength. The light transmitting region constitutes at least a part of the upper surface 213a and the lower surface 213b of the lid portion 213. For example, the light transmitting region of the lid portion 213 can be formed by using sapphire as a main material. Sapphire is a material with relatively high transmittance and relatively high strength. As the main material of the light transmitting region of the lid portion 213, in addition to sapphire, materials having transmissivity, such as quartz, silicon carbide, or glass, may be used. A portion, other than the light transmitting region, of the lid portion 213 may be formed of a light shielding member, or may be formed monolithically with the light transmitting region using the same material as that of the light transmitting region.

### Light-Emitting Element 220

In the illustrated example of the light-emitting device 200, single light-emitting element 220 is mounted. A plurality of the light-emitting elements may be mounted in the light-emitting device 200. The light-emitting element 220 is, for example, a semiconductor laser element. The light-emitting element 220 is not limited to a semiconductor laser element, and may be, for example, a light-emitting diode (LED) or an organic light-emitting diode (OLED). In the light-emitting device 200 exemplarily illustrated in FIGS. 1 to 4, a semiconductor laser element is used as the light-emitting element 220.

The light-emitting element 220 has, for example, a rectangular outer shape in the top view. Further, a lateral surface joined with one of two short sides of this rectangle is an emitting end surface for light emitted from the light-emitting element 220. An upper surface and a lower surface of the light-emitting element 220 each have a larger area than the area of the emitting end surface.

The light emitted from the light-emitting element 220 is light that is preferably converted to its desired state for use. For example, when a semiconductor laser element is used, and light emitted from the light-emitting device is irradiated to a human body, it may be preferable to diffuse laser light before emission. In this case, it is preferable that a state of the light emitted from the light-emitting element 220 be converted by using a diffusion member and the like, and then the light be emitted to the outside of the light-emitting device. Without being limited to such an example, the light emitted from the light-emitting element is preferably converted into a desired state for use in view of a property of the light and a final usage form.

A light-emitting element that emits blue light can be used as the light-emitting element 220. The “light-emitting element that emits blue light” means that emitted light having a light emission peak wavelength in a range from 405 nm to 494 nm is used. As the light-emitting element 220, it is preferable to use a light-emitting element emitting light having a peak wavelength in a range from 430 nm to 480 nm. Examples of such the light-emitting element 220 include a semiconductor laser element including a nitride semiconductor. As the nitride semiconductor, for example, GaN, InGaN, or AlGaN can be used.

The emission peak of the light emitted from the light-emitting element 220 may not be limited to this. For example, the light emitted from the light-emitting element 220 may be visible light having a wavelength outside the wavelength range described above including green light and red light in addition to the blue light, ultraviolet light, or infrared light.

Here, a case in which the light-emitting element 220 is a semiconductor laser element will be described. The light (laser light) emitted from the light-emitting element 220 spreads and forms an elliptical far field pattern (hereinafter referred to as “FFP”) on a plane parallel to the emitting end surface. Here, the FFP indicates a shape and a light intensity distribution of the emitted light at a position away from the emitting end surface.

Based on the FFP, having an elliptical shape, of the light emitted from the light-emitting element 220, a direction passing through a major axis of the elliptical shape is referred to as a fast axis direction of the FFP, and a direction passing through a minor axis of the elliptical shape is referred to as a slow axis direction of the FFP. The fast axis direction of the FFP in the light-emitting element 220 may coincide with a layering direction in which a plurality of semiconductor layers including an active layer of the light-emitting element 220 are layered.

Further, light passing through the center of the elliptical shape of the FFP, in other words, light having a peak intensity in the light intensity distribution of the FFP, is referred to as light traveling on an optical axis or light passing through an optical axis. Further, an optical path of the light traveling on the center of the elliptical shape of the FFP is referred to as the optical axis of the light.

### Submount 230

The submount 230 has, for example, a rectangular parallelepiped shape and has a lower surface, an upper surface, and one or a plurality of lateral surfaces. In the top view, the submount 230 has a smaller width in a direction perpendicular to a drawing plane than a width in a direction of the optical axis of the light-emitting element 220 and a direction perpendicular to this optical axis direction. The shape may not be limited to a rectangular parallelepiped. The submount 230 is formed by using, for example, aluminum nitride or silicon carbide, but may be formed by using silicon nitride, diamond, copper, aluminum oxide, and the like, or a combination of these materials. Further, for example, a conductive film is provided at an upper surface of the submount 230.

### Submount 235

The submount 235 can be formed of, for example, the same material as that of the submount 230. The submount 235 may be formed of a material different from that of the submount 230.

### Wavelength Conversion Member 240

The wavelength conversion member 240 has the wavelength conversion portion 241 and an enclosing portion 242. A lateral surface of the wavelength conversion member 240 has a recessed portion 240x. A part of the recessed portion 240x is configured of the wavelength conversion portion 241, and another part of the recessed portion 240x is configured of the enclosing portion 242.

The wavelength conversion portion 241 has an upper surface 241a, a lower surface 241b that is a surface opposite to the upper surface 241a, and one or a plurality of lateral surfaces. The lower surface 241b of the wavelength conversion portion 241 faces the placement surface 211a of the bottom portion. In the example in FIG. 5, the wavelength conversion portion 241 has an incident lateral surface 241i, a first lateral surface 241c, a second lateral surface 241d, a third lateral surface 241e, and a fourth lateral surface 241f as the plurality of lateral surfaces.

The first lateral surface 241c, the second lateral surface 241d, the third lateral surface 241e, and the fourth lateral surface 241f are joined with an outer edge of the upper surface 241a and an outer edge of the lower surface 241b. The third lateral surface 241e is joined with the first lateral surface 241c and the fourth lateral surface 241f The fourth lateral surface 241f is joined with the second lateral surface 241d and the third lateral surface 241e. The first lateral surface 241c and the fourth lateral surface 241f are not joined with each other. The second lateral surface 241d and the third lateral surface 241e are not joined with each other.

The first lateral surface 241c and the second lateral surface 241d are joined with each other on an upper side, and are each joined with the incident lateral surface 241i on a lower side. A lower side of the incident lateral surface 241i is joined with the outer edge of the lower surface 241b. The lower side of the incident lateral surface 241i is recessed from a connecting portion side of the first lateral surface 241c and the second lateral surface 241d toward a connecting portion side of the third lateral surface 241e and the fourth lateral surface 241f.

In the top view, the first lateral surface 241c and the fourth lateral surface 241f may be parallel to each other. In the top view, the second lateral surface 241d and the third lateral surface 241e may be parallel to each other. In the top view, the first lateral surface 241c and the second lateral surface 241d may be perpendicular to each other, the first lateral surface 241c and the third lateral surface 241e may be perpendicular to each other, the third lateral surface 241e and the fourth lateral surface 241f may be perpendicular to each other, and the fourth lateral surface 241f and the second lateral surface 241d may be perpendicular to each other.

The wavelength conversion portion 241 is irradiated with the light, and thus a base material of the wavelength conversion portion 241 is preferably formed by using, as the main material, an inorganic material that is not easily decomposed by irradiation of the light. The main material is, for example, a ceramic. In a case in which the main material of the wavelength conversion portion 241 is ceramic, examples of the ceramic include aluminum oxide, aluminum nitride, silicon oxide, yttrium oxide, zirconium oxide, or magnesium oxide. The main material of the ceramic is preferably selected from a material having a melting point in a range from 1300° C. to 2500° C. such that deterioration such as thermal deformation or discoloration is not generated in the wavelength conversion portion 241. Here, the “main material” of a specific member refers to a material that occupies the largest ratio of the components in terms of a weight ratio or a volume ratio. The “main material” may also include that no other materials are contained, that is, only the main material is used to form the component. The wavelength conversion portion 241 may be formed of a material other than the ceramic as the main material.

The wavelength conversion portion 241 contains a phosphor. The wavelength conversion portion 241 can be formed by sintering, for example, a phosphor and aluminum oxide and the like. For example, for the wavelength conversion portion 241, ceramic substantially formed of only phosphor, which is obtained by sintering powder of the phosphor, may be used. The content of the phosphor can be in a range from 0.05 vol % to 100 vol % with respect to the total volume of the ceramic. Further, the wavelength conversion portion 241 may be formed of a single crystal of the phosphor.

Examples of the phosphor include yttrium aluminum garnet (YAG) activated with cerium, lutetium aluminum garnet (LAG) activated with cerium, silicate ((Sr, Ba)₂SiO₄) activated with europium, αSiAlON phosphor, and βSiAlON phosphor. Among them, the YAG phosphor has good heat resistance.

The enclosing portion 242 has an upper surface 242a, a lower surface 242b that is a surface opposite to the upper surface 242a, one or a plurality of inner lateral surfaces joining an inner edge of the upper surface 242a and an inner edge of the lower surface 242b, and one or a plurality of outer lateral surfaces joining an outer edge of the upper surface 242a and an outer edge of the lower surface 242b. The enclosing portion 242 preferably has a reflectance of light in a range from 80% to 100%, and more preferably in a range from 90% to 100% on the one or the plurality of inner lateral surfaces.

The enclosing portion 242 is surrounding the wavelength conversion portion 241. The upper surface 242a of the enclosing portion 242 surrounds the upper surface 241a of the wavelength conversion portion 241 in the top view. The one or the plurality of inner lateral surfaces of the enclosing portion 242 cover the first lateral surface 241c, the second lateral surface 241d, the third lateral surface 241e, and the fourth lateral surface 241f of the wavelength conversion portion 241. The enclosing portion 242 does not cover the incident lateral surface 241i, and the incident lateral surface 241i is exposed from the enclosing portion 242.

The upper surface 242a of the enclosing portion 242 is located on the same plane as the upper surface 241a of the wavelength conversion portion 241. Similarly, the lower surface 242b of the enclosing portion 242 is located on the same plane as the lower surface 241b of the wavelength conversion portion 241. The upper surface 242a of the enclosing portion 242 may not be located on the same plane as the upper surface 241a of the wavelength conversion portion 241. Similarly, the lower surface 242b of the enclosing portion 242 may not be located on the same plane as the lower surface 241b of the wavelength conversion portion 241. In the example illustrated by the drawings, in the top view, all four sides that connect four outer lateral surfaces and the upper surface 242a of the enclosing portion 242 may be non-parallel to four sides that connect the upper surface 241a and four lateral surfaces of the wavelength conversion portion 241.

The enclosing portion 242 further has a protruding portion 242t. In the present specification, in the enclosing portion 242, a portion protruding from the incident lateral surface 241i along a direction in which the light-emitting element 220 is located, on the side above the incident lateral surface 241i is referred to as the “protruding portion 242t”.

The protruding portion 242t is formed of at least a part of the upper surface 242a of the enclosing portion 242, an end surface 242e being one of the outer lateral surfaces of the enclosing portion 242, a lower surface 242c, and at least a part of an outer lateral surface 242d of the enclosing portion 242. The lower surface 242b of the enclosing portion 242 is not included in the protruding portion 242t.

The enclosing portion 242 is, for example, a sintered compact formed by using ceramic as the main material. The ceramic used for the main material includes, for example, aluminum oxide, aluminum nitride, silicon oxide, yttrium oxide, zirconium oxide, and magnesium oxide. A reflectance can be improved by reducing the density of the main material of the sintered compact. The enclosing portion 242 is more preferably formed by using ceramic having high reflectivity as the main material. Here, “having high reflectivity” means that a reflectance of light having a specific peak wavelength is 80% or more. Examples of the ceramic having high reflectivity include aluminum oxide. The enclosing portion 242 may not contain ceramic as the main material. The enclosing portion 242 may be formed by using, for example, a conductive material such as metal, a composite of ceramic and metal, a resin, and the like.

In the wavelength conversion member 240, the wavelength conversion portion 241 and the enclosing portion 242 can be monolithically formed. The wavelength conversion member 240 may be obtained by individually forming the wavelength conversion portion 241 and the enclosing portion 242 and bonding them together. The wavelength conversion portion 241 and the enclosing portion 242 are, for example, a monolithic sintered compact. In the wavelength conversion member 240, a surface of the recessed portion 240x has the incident lateral surface 241i of the wavelength conversion portion 241, the outer lateral surface 242d of the enclosing portion 242, and the lower surface 242c of the protruding portion 242t.

The wavelength conversion member 240 may include an anti-reflective film on the upper surface. The anti-reflective film can be provided at the upper surface 241a of the wavelength conversion portion 241 and/or the upper surface 242a of the enclosing portion 242. The wavelength conversion member 240 may include a reflective film on the lower surface 241b of the wavelength conversion portion 241 and/or the lower surface 242b of the enclosing portion 242. The wavelength conversion member 240 may include a reflective film on the incident lateral surface 241i.

### Protective Element 250

The protective element 250 is a component for protecting specific elements such as semiconductor laser elements. The protective element 250 is a component for preventing specific elements such as semiconductor laser elements from being broken by an excessive current flowing therethrough, for example. For example, a Zener diode formed of Si can be used as the protective element 250. For example, the protective element 250 may be a component for measuring temperature so that a specific element does not fail due to the temperature environment. For example, a thermistor can be used as the temperature measuring element. The temperature measuring element may be disposed near an emitting end surface 220a of the light-emitting element 220.

### First Wiring 271 to Fifth Wiring 275

The first wiring 271, the second wiring 272, the third wiring 273, the fourth wiring 274, and the fifth wiring 275 are formed of a conductor having a linear shape with bonding portions at both ends. In other words, the first wiring 271 to the fifth wiring 275 include the bonding portions that are bonded to other components, at both ends of the linear portion. The first wiring 271 to the fifth wiring 275 are used for electrical connection between two components. For example, a metal wire can be used as the first wiring 271 to the fifth wiring 275. Examples of the metal include gold, aluminum, silver, copper, and tungsten.

### Light-Emitting Device 200

Next, the light-emitting device 200 will be described.

The one or the plurality of light-emitting elements 220 are disposed at the placement surface 211a of the bottom portion 211. The light-emitting element 220 is disposed inward of the frame portion 212 in the top view. In the example illustrated by the drawings, one light-emitting element 220 is disposed at the placement surface 211a. The light-emitting element 220 is further surrounded by the frame portion 212. The light-emitting element 220 emits light that travels laterally from the emitting end surface. The light emitted from the light-emitting element 220 is, for example, blue light. The light emitted from the light-emitting element 220 is not limited to the blue light. In the example illustrated by the drawings, the light-emitting element 220 is a semiconductor laser element.

For example, the light-emitting element 220 is disposed on the submount 230 disposed at the placement surface 211a of the bottom portion 211. For example, the submount 230 is bonded onto a metal film 269 provided at the placement surface 211a of the bottom portion 211 via a metal adhesive. Examples of the metal film 269 include Ni/Au (e.g., metal film laminated in order of Ni, Au), Ti/Pt/Au (e.g., metal film laminated in order of Ti, Pt, Au), and the like. Examples of the metal adhesive include AuSn. Heat generated by driving the light-emitting element 220 can be effectively cooled by disposing the light-emitting element 220 on the submothe 230. The light-emitting element 220 may be directly disposed on the placement surface 211a of the bottom portion 211 instead of being disposed on the submount 230.

The light-emitting element 220 is disposed such that the emitting end surface 220a faces the incident lateral surface 241i of the wavelength conversion portion 241. The emitting end surface 220a of the light-emitting element 220 may be, for example, parallel or perpendicular to one inner lateral surface 212c or one outer lateral surface 212d of the frame portion 212.

The wavelength conversion member 240 is disposed at the placement surface 211a of the bottom portion 211. The wavelength conversion member 240 is disposed inward of the frame portion 212 in the top view. The lower surface 241b of the wavelength conversion portion 241 and the lower surface 242b of the enclosing portion 242 face the placement surface 211a of the bottom portion 211. The wavelength conversion member 240 is disposed at a portion to which the light emitted from the light-emitting element 220 travels. More specifically, the wavelength conversion member 240 is disposed at a position on which light emitted from the light-emitting element 220 and traveling laterally is incident.

Furthermore, the wavelength conversion member 240 is located on an optical axis OA of the light emitted laterally from the light-emitting element 220. In the example illustrated by the drawings, a traveling direction of the light that is emitted from the light-emitting element 220 and travels along the optical axis OA is in a constant direction until the light is incident on the wavelength conversion portion 241 of the wavelength conversion member 240. In the example illustrated by the drawings, another member is not present on an optical path between where the light is emitted from the light-emitting element 220 and where the light is incident on the incident lateral surface 241i of the wavelength conversion portion 241. This allows the light-emitting device 200 to be reduced in size. Another member such as a collimating lens may be disposed between the light-emitting element 220 and the wavelength conversion portion 241.

For example, the wavelength conversion member 240 is disposed on the submount 235 disposed at the placement surface 211a of the bottom portion 211. For example, together with the submount 230, the submount 235 is bonded, via a metal adhesive, onto the metal film 269 provided at the placement surface 211a of the bottom portion 211. A height of an upper surface of the submount 235 on which the wavelength conversion member 240 is disposed is preferably lower than a height of the upper surface of the submount 230 on which the light-emitting element 220 is disposed. In this way, light that travels below the optical axis OA of the light emitted from the light-emitting element 220 can be efficiently taken into the wavelength conversion portion 241 from the incident lateral surface 241i. Heat generated from the wavelength conversion member 240 can be effectively cooled by disposing the wavelength conversion member 240 on the submount 235. The wavelength conversion member 240 may be disposed at the submount 230 at which the light-emitting element 220 is disposed, or may be directly disposed on the placement surface 211a of the bottom portion 211.

The wavelength conversion portion 241 of the wavelength conversion member 240 has an incident lateral surface on which light emitted from the emitting end surface 220a of the light-emitting element 220 and traveling laterally is incident, and an emitting surface from which the incident light having a wavelength converted is emitted. In the example illustrated by the drawings, the incident lateral surface 241i and the upper surface 241a of the wavelength conversion portion 241 serve as the incident lateral surface and the emitting surface, respectively. The upper surface 241a of the wavelength conversion portion 241 emits the light having the wavelength converted upward. The enclosing portion 242 of the wavelength conversion member 240 surrounds the wavelength conversion portion 241. The emitting surface from which light is emitted may be provided at the lateral surface of the wavelength conversion member 240.

In a plane including the lower surface 241b of the wavelength conversion portion 241, an extension line of the first lateral surface 241c and an extension line of the second lateral surface 241d of the wavelength conversion portion 241 are in contact with each other on a side closer to the light-emitting element 220 than the incident lateral surface 241i. In a bottom view, the third lateral surface 241e and the fourth lateral surface 241f of the wavelength conversion portion 241 are joined with each other on a side opposite to the light-emitting element 220 with respect to the incident lateral surface 241i.

The protruding portion 242t of the enclosing portion 242 included in the wavelength conversion member 240 protrudes toward a side closer to the light-emitting element 220 than the incident lateral surface 241i and at a position above the light-emitting element 220. The protruding portion 242t protrudes toward a side closer to the light-emitting element 220 than an end portion, on the light-emitting element 220 side, of the lower surface of the wavelength conversion member 240. The protruding portion 242t overlaps the emitting end surface 220a of the light-emitting element 220 in the top view. In the top view, the emitting end surface 220a of the light-emitting element 220 is located directly below the recessed portion 240x (i.e., the emitting end surface 220a overlaps the recessed portion 240x in the top view). In the top view, the emitting end surface 220a of the light-emitting element 220 is located directly below the lower surface 242c.

The protruding portion 242t is preferably disposed so as to overlap the entire emitting end surface 220a of the light-emitting element 220 in the top view. Such an arrangement can suppress leakage light that is not incident on the wavelength conversion portion 241 of the light emitted from the light-emitting element 220. By such an arrangement, a distance between the light-emitting element 220 and the wavelength conversion member 240 can be reduced, and the size of the light-emitting device 200 can be reduced. When the light-emitting device 200 includes the plurality of light-emitting elements 220, the emitting end surfaces 220a of all of the light-emitting elements 220 and the one or more protruding portions 242t preferably overlap each other in the top view. In this way, leakage light traveling above the optical axis OA of all of the light-emitting elements 220 can be reduced.

For example, the wavelength conversion portion 241 is disposed at a position through which the optical axis OA of the light emitted from the light-emitting element 220 passes in the top view. In the top view, a shape of the upper surface 241a of the wavelength conversion portion 241 may be line symmetric with the optical axis OA as a reference axis. In the top view, a shape of the upper surface 242a of the enclosing portion 242 may be line symmetric with the optical axis OA as the reference axis.

The light emitted from the light-emitting element 220 travels in a direction toward the wavelength conversion member 240, and is incident on the incident lateral surface 241i of the wavelength conversion portion 241 exposed from the enclosing portion 242. At least a part of the incident lateral surface 241i of the wavelength conversion portion 241 is located below the optical axis OA. In this way, light that travels below the optical axis OA of the light emitted from the light-emitting element 220 can be efficiently taken into the wavelength conversion portion 241 from the incident lateral surface 241i. Light is emitted from the upper surface 241a of the wavelength conversion portion 241 on the basis of the light incident on the incident lateral surface 241i. Here, the light emitted on the basis of the incident light is, for example, incident light and, for example, light that has been wavelength-converted on the basis of the incident light.

The light having the wavelength converted by the wavelength conversion member 240 is safer than laser light, which causes less damage when being directly viewed. Even when the light emitted from the light-emitting device 200 is laser light, the light that passes through the wavelength conversion member 240 and is emitted from the wavelength conversion member 240 is safe light which causes less damage when being directly viewed. This is because the laser light is diffused by passing through the wavelength conversion member 240.

The light emitted from the light-emitting element and/or the light having the wavelength converted by the wavelength conversion portion 241 is reflected by the enclosing portion 242, travels to the upper surface 241a side of the wavelength conversion portion 241, and then is emitted from the upper surface 241a of the wavelength conversion portion 241. As a result, it is possible to efficiently emit light from the upper surface 241a.

One lateral surface of two lateral surfaces of the light-emitting element 220 joined with the emitting end surface 220a faces a lateral surface of the first stepped portion 214. For example, the one lateral surface of the two lateral surfaces of the light-emitting element 220 joined with the emitting end surface 220a is parallel to the lateral surface of the first stepped portion 214. The other lateral surface of the two lateral surfaces of the light-emitting element 220 joined with the emitting end surface 220a faces a lateral surface of the second stepped portion 215. For example, the other lateral surface of the two lateral surfaces of the light-emitting element 220 joined with the emitting end surface 220a is parallel to the lateral surface of the second stepped portion 215. For example, the upper surface 214a of the first stepped portion 214 and the upper surface 215a of the second stepped portion 215 are located at a position lower than a height of the upper surface 241a of the wavelength conversion portion 241 with the placement surface 211a of the bottom portion 211 as a reference. With such a height, light emitted upward from the upper surface 241a is not irradiated directly onto the first stepped portion 214 and the second stepped portion 215, and light shielding and light absorption by the stepped portion do not occur, thereby suppressing a loss of light emitted from the wavelength conversion portion.

For example, the position of the upper surface 214a of the first stepped portion 214 and the position of the upper surface 215a of the second stepped portion 215 are higher than a height of the upper surface of the light-emitting element 220 with the placement surface 211a of the bottom portion 211 as a reference.

In the light-emitting device 200, the light-emitting element 220 is electrically connected to the conductive film provided at the bottom portion 211 and the frame portion 212 by the first wiring 271, the second wiring 272, the third wiring 273, and the fourth wiring 274. In other words, in the light-emitting device 200, the light-emitting element 220 is electrically connected to the conductive film provided at the base member 210 by the first wiring 271, the second wiring 272, the third wiring 273, and the fourth wiring 274. The protective element 250 may be connected in parallel with the light-emitting element 220 by disposing the fifth wiring 275. The light-emitting device 200 illustrated in the drawings is an example in which the protective element 250 is a Zener diode, but in a case in which the protective element 250 is a temperature measuring element, the connection of the wirings may be different from that in the drawing. The electrical connection between wiring (the first wiring 271, the second wiring 272, the third wiring 273, the fourth wiring 274, and the fifth wiring 275), components (the light-emitting element 220, the protective element 250), and the like will be described below.

The lid portion 213 is disposed at the upper surface 212a of the frame portion 212. The lid portion 213 is supported by the upper surface 212a of the frame portion 212, and is disposed above the light-emitting element 220 surrounded by the frame portion 212. An outer peripheral portion of the lower surface of the lid portion 213 is bonded to, for example, the upper surface 212a of the frame portion 212. For example, a metal film provided at the outer peripheral portion of the lower surface of the lid portion 213, and a metal film provided at the upper surface 212a of the frame portion 212 are bonded via AuSn and the like.

The lid portion 213 is bonded to the upper surface 212a of the frame portion 212, and thus a sealed space at which the light-emitting element 220 and the wavelength conversion member 240 are disposed is formed. Further, this sealed space may be formed in a hermetically sealed state. This sealed space is in the sealed state, thus suppressing collection of dust such as organic substances on the emitting end surface 220a of the light-emitting element 220.

The lid portion 213 may have the light transmitting region that transmits light emitted from the upper surface 241a of the wavelength conversion portion 241, and emits the light to the outside. In other words, the light emitted from the upper surface 241a of the wavelength conversion portion 241 to the lid portion 213 side may be transmitted through the light transmitting region of the lid portion 213, and emitted to the outside the light-emitting device 200. The entire lid portion 213 may be the light transmitting region. The light transmitting region of the lid portion 213 transmits 70% or more of the light emitted from the light-emitting element 220 and the light emitted from the wavelength conversion member 240.

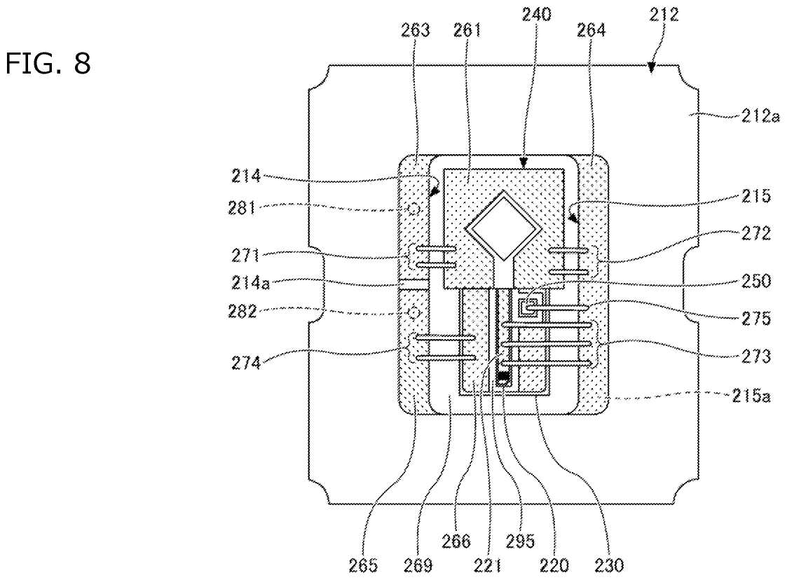

FIG. 8 is a schematic top view illustrating a current path of the light-emitting element 220 in the light-emitting device 200 according to the first embodiment. The current path of the light-emitting element 220 will be described with reference to FIG. 8 in addition to FIGS. 1 to 7. In FIG. 8, a part of the conductive film is illustrated in a dot pattern for the sake of description.

The enclosing portion 242 has a wiring region serving as a part of the current path of the light-emitting element 220. Specifically, in the light-emitting device 200, a first conductive film 261 serving as the wiring region is provided at the upper surface 242a of the enclosing portion 242. The first conductive film 261 surrounds the upper surface 241a of the wavelength conversion portion 241 in the top view. Specifically, the first conductive film 261 is provided at a portion of the wavelength conversion member 240 excluding the upper surface 241a of the wavelength conversion portion 241, that is, at least a part of the upper surface 242a of the enclosing portion 242. It is preferable that an area in which the first conductive film 261 covers the upper surface 242a of the enclosing portion 242 is 80% or more of an entire area of the upper surface 242a of the enclosing portion 242. The first conductive film 261 does not have to annularly surround the upper surface 241a of the wavelength conversion portion 241. In the top view, the enclosing portion 242 has an unoccupied region at which the first conductive film 261 is not provided, in other words, the first conductive film 261 would have an annular shape if the first conductive film 261 was provided at a position of the unoccupied region. The first conductive film 261 may be provided at the upper surface 242a of the enclosing portion 242 without the unoccupied region.

In the example in FIG. 8, in the top view, an inner edge of the first conductive film 261 is disposed along the first lateral surface 241c, the second lateral surface 241d, the third lateral surface 241e, and the fourth lateral surface 241f, except in the vicinity of the connecting portion of the first lateral surface 241c and the second lateral surface 241d of the wavelength conversion portion 241. The inner edge of the first conductive film 261 does not reach the first lateral surface 241c, the second lateral surface 241d, the third lateral surface 241e, and the fourth lateral surface 241f In other words, in the top view, a substantially constant gap is provided between the inner edge of the first conductive film 261 and the first lateral surface 241c, the second lateral surface 241d, the third lateral surface 241e, and the fourth lateral surface 241f, except in the vicinity of the connecting portion of the first lateral surface 241c and the second lateral surface 241d. In the example in FIG. 8, in the top view, an outer edge of the first conductive film 261 coincides with the outer edge of the upper surface 242a of the enclosing portion 242. In other words, the first conductive film 261 is provided up to an outermost side of the upper surface 242a of the enclosing portion 242. In the top view, the outer edge of the first conductive film 261 may not coincide with the outer edge of the upper surface 242a of the enclosing portion 242.

In the top view, the first conductive film 261 is provided from one region to the other region when the upper surface of the wavelength conversion member 240 is divided into two parts by a virtual straight line passing through the optical axis OA. In this way, the first wiring 271 and the second wiring 272 are easily bonded to the wavelength conversion member 240.

On the upper surface 214a of the first stepped portion 214, the third conductive film 263 and the fifth conductive film 265 are separated from each other along one side of the inner edge shape of the upper surface 212a of the frame portion 212. In the example in FIG. 8, in the top view, the third conductive film 263 is provided at a position substantially facing the lateral surface of the wavelength conversion member 240. In the top view, the fifth conductive film 265 is provided at a position substantially facing the lateral surface of the submount 230. In the top view, the third conductive film 263 can be provided in a region sandwiched between a straight line including a side, which is parallel to the optical axis of the light-emitting element 220, of the sides of the wavelength conversion member 240, and a straight line including a side, which is parallel to the optical axis of the light-emitting element 220, of the inner lateral surface 212c of the frame portion 212. Further, in the top view, the fifth conductive film 265 can be provided in a region sandwiched between a straight line including a side, which is parallel to the optical axis of the light-emitting element 220, of the sides of the submount 230, and a straight line including a side, which is parallel to the optical axis of the light-emitting element 220, of the inner lateral surface 212c of the frame portion 212. The third conductive film 263 and the fifth conductive film 265 may not be necessarily provided at the upper surface 214a of the first stepped portion 214.

The third conductive film 263 is electrically connected to the first conductive film 261 being the wiring region provided at the upper surface 242a of the enclosing portion 242 via the first wiring 271. In other words, the current path of the light-emitting element 220 includes the third conductive film 263, the first wiring 271, and the first conductive film 261 being the wiring region. The third conductive film 263 and the first wiring 271 are physically bonded to each other, and the first wiring 271 and the first conductive film 261 are physically bonded to each other. By the physical bonding, movement of the wavelength conversion member 240 can be limited even when the wavelength conversion member 240 is not fixed to the base member 210, and an occurrence of an abnormality in which the light emitted from the light-emitting element 220 is not incident on the wavelength conversion portion 241 can be reduced. In the example in FIG. 8, two first wirings 271 are provided, but only one first wiring 271 may be provided, or three or more first wirings 271 may be provided.

The fourth conductive film 264 is provided at the upper surface 215a of the second stepped portion 215. In the example in FIG. 8, in the top view, the fourth conductive film 264 is provided from a position substantially facing the lateral surface of the wavelength conversion member 240 to a position substantially facing the lateral surface of the submount 230. In the top view, the fourth conductive film 264 may be provided at the entire upper surface 215a of the second stepped portion 215, or may be provided at a part of the upper surface 215a of the second stepped portion 215.

In the top view, a virtual straight line passing through the end surface 242e of the wavelength conversion member 240 and being parallel to the end surface 242e passes through the fourth conductive film 264. In this way, the fourth conductive film 264 is easily used when the wavelength conversion member 240 is used as a part of the current path of the light-emitting element 220. In the top view, a virtual straight line passing through a region where the third conductive film 263 and the fifth conductive film 265 are separated and extending in a direction perpendicular to the optical axis OA may pass through the fourth conductive film 264.

In the top view, the fourth conductive film 264 extends across an entire length in a direction parallel to the optical axis OA in a region sandwiched between two virtual straight lines. One of the two virtual straight lines passes through a point, closest to the light-emitting element 220, of the wavelength conversion portion 241 in the direction parallel to the optical axis OA and is perpendicular to the optical axis OA. Another one of the two virtual straight lines passes through a middle point of the light-emitting element 220 in the direction parallel to the optical axis OA and is perpendicular to the optical axis OA. In this way, wiring lengths of the second wiring 272 and the third wiring 273 can be shortened, and a load on the wiring can be reduced.

The first conductive film 261 being the wiring region provided at the upper surface 242a of the enclosing portion 242 is electrically connected to the fourth conductive film 264 via the second wiring 272. In other words, the current path of the light-emitting element 220 includes the third conductive film 263, the first wiring 271, the first conductive film 261 being the wiring region, the second wiring 272, and the fourth conductive film 264. Further, the first conductive film 261 and the second wiring 272 are physically bonded to each other, and the second wiring 272 and the fourth conductive film 264 are physically bonded to each other. By the physical bonding, movement of the wavelength conversion member 240 can be limited even when the wavelength conversion member 240 is not fixed to the base member 210, and an occurrence of an abnormality in which the light emitted from the light-emitting element 220 is not incident on the wavelength conversion portion 241 can be reduced. In the example in FIG. 8, two second wirings 272 are provided, but only one second wiring 272 may be provided, or three or more second wirings 272 may be provided.

A first electrode 221 is provided at the upper surface of the light-emitting element 220. The fourth conductive film 264 is electrically connected to the first electrode 221 of the light-emitting element 220 via the third wiring 273. In other words, the current path of the light-emitting element 220 includes the third conductive film 263, the first wiring 271, the first conductive film 261 being the wiring region, the second wiring 272, the fourth conductive film 264, the third wiring 273, and the first electrode 221. Further, the fourth conductive film 264 and the third wiring 273 are physically bonded to each other, and the third wiring 273 and the first electrode 221 are physically bonded to each other. In the example in FIG. 8, three third wirings 273 are provided, but only one third wiring 273 may be provided, two third wirings 273 may be provided, or four or more third wirings 273 may be provided.

A second electrode is provided at the lower surface of the light-emitting element 220. The second electrode of the light-emitting element 220 is electrically connected to the fifth conductive film 265 provided at the upper surface 214a of the first stepped portion 214 via the fourth wiring 274. In the example in FIG. 8, the light-emitting element 220 is mounted on a sixth conductive film 266 provided at the upper surface of the submount 230. The second electrode provided at the lower surface of the light-emitting element 220 is bonded to the sixth conductive film 266 via a first bonding portion 295 having conductivity. An example of the first bonding portion 295 having conductivity includes AuSn. The sixth conductive film 266 is electrically connected to the fifth conductive film 265 via the fourth wiring 274.

In other words, the current path of the light-emitting element 220 includes the third conductive film 263, the first wiring 271, the first conductive film 261 being the wiring region, the second wiring 272, the fourth conductive film 264, the third wiring 273, the first electrode 221, the second electrode of the light-emitting element 220, the first bonding portion 295, the sixth conductive film 266, the fourth wiring 274, and the fifth conductive film 265. The sixth conductive film 266 and the fourth wiring 274 are physically bonded to each other, and the fourth wiring 274 and the fifth conductive film 265 are physically bonded to each other. In the example in FIG. 8, two fourth wirings 274 are provided, but only one fourth wiring 274 may be provided, or three or more fourth wirings 274 may be provided.

The third conductive film 263, the first wiring 271, the first conductive film 261 being the wiring region, the second wiring 272, the fourth conductive film 264, the third wiring 273, the first electrode 221, the second electrode of the light-emitting element 220, the fourth wiring 274, and the fifth conductive film 265 are present in the sealed space formed by the lid portion 213 and the base member 210. In this way, collection of dust, such as organic substances, on the conductive films and the wirings can be suppressed.

The third conductive film 263 is electrically connected to the first external connection electrode 291 provided at the lower surface 212b of the frame portion 212 via a first via wiring 281 passing through the first stepped portion 214. Further, the fifth conductive film 265 is electrically connected to the second external connection electrode 292 provided at the lower surface 212b of the frame portion 212 via a second via wiring 282 passing through the first stepped portion 214.

That is, the current path of the light-emitting element 220 includes the first external connection electrode 291, the first via wiring 281, the third conductive film 263, the first wiring 271, the first conductive film 261 being the wiring region, the second wiring 272, the fourth conductive film 264, the third wiring 273, the first electrode 221, the second electrode of the light-emitting element 220, the fourth wiring 274, the fifth conductive film 265, the second via wiring 282, and the second external connection electrode 292.

Further, a current path connected from the first via wiring 281 to the second via wiring 282 through the light-emitting element 220 is present in the sealed space formed of the lid portion 213 and the base member 210. In this way, collection of dust, such as organic substances, on the conductive films and the wirings can be suppressed. Here, the current path connected from the first via wiring 281 to the second via wiring 282 does not include the first via wiring 281 and the second via wiring 282, and is the current path connecting between the first via wiring 281 and the second via wiring 282.

For example, a metal film can be used as the first conductive film 261, the third conductive film 263, the fourth conductive film 264, the fifth conductive film 265, and the sixth conductive film 266. Examples of the metal film include Ni/Au (metal film layered in the order of Ni, Au), Ti/Pt/Au (metal film layered in the order of Ti, Pt, Au), and the like. A film such as indium tin oxide (ITO) other than the metal film may be used as the first conductive film 261, the third conductive film 263, the fourth conductive film 264, the fifth conductive film 265, and the sixth conductive film 266.

The enclosing portion 242 of the wavelength conversion member 240 may be formed by using a conductive material such as aluminum. In that case, the upper surface 242a of the enclosing portion 242 can be used as the wiring region without providing the conductive film on the upper surface 242a of the enclosing portion 242.

The light-emitting device 200 is configured such that the first conductive film 261 provided at the upper surface 242a of the enclosing portion 242 of the wavelength conversion member 240 is included in the current path of the light-emitting element 220. Thus, when a crack, detachment, and the like occur in the wavelength conversion member 240, and the first conductive film 261 is disconnected, or the first wiring 271 and/or the second wiring 272 is disconnected, a current will not flow to the light-emitting element 220. As a result, when a crack, detachment, and the like occur in the wavelength conversion member 240, light emission of the light-emitting element 220 is stopped, and thus power supply to the light-emitting element 220 is directly stopped by the abnormality occurring in the wavelength conversion member 240. In this way, a safety-related measure for the light-emitting device 200 can be taken.

The first conductive film 261 is provided at the upper surface 242a of the enclosing portion 242, and thus, even when only a vicinity of the upper surface of the wavelength conversion member 240 is damaged, the first conductive film 261 is disconnected, and a current will not flow to the light-emitting element 220. On the other hand, for example, in a case in which the conductive film is provided at the lower surface 242b of the enclosing portion 242, when only a vicinity of the upper surface of the wavelength conversion member 240 is damaged, a current continues to flow through the light-emitting element 220. Thus, by providing the first conductive film 261 on the upper surface 242a of the enclosing portion 242, the safety of the light-emitting device 200 can be further improved as compared to when the first conductive film 261 is provided at the lower surface 242b of the enclosing portion 242.

In a case in which the first conductive film 261 is provided such that a unoccupied region is provided at a part of the upper surface 242a of the enclosing portion 242 and a current cannot flow across the unoccupied region, for example, the first conductive film 261 is disconnected even when a crack occurs, at one place, from the upper surface 241a of the wavelength conversion portion 241 to the lateral surface of the wavelength conversion member 240 through the first conductive film 261. In contrast, in a case in which the first conductive film 261 is provided without the unoccupied region around the upper surface 241a of the wavelength conversion portion 241, when the crack as described above occurs at one place, the first conductive film on an opposite side of the crack across the upper surface 241a of the wavelength conversion portion 241 is in a conductive state. Thus, even when the crack occurs, the current path is not disconnected, and the light-emitting element 220 may remain to be turned on. Thus, when the first conductive film 261 surrounds the upper surface 241a of the wavelength conversion portion 241 while providing the unoccupied region, the safety of the light-emitting device 200 can be improved more than when the first conductive film 261 is provided without the unoccupied region.

It can be said that a risk to the safety is higher when a region of the upper surface 242a of the enclosing portion 242 on a side farther from the light-emitting element 220 is damaged than when a region constituting the protruding portion 242t is damaged. The unoccupied region is provided in a portion of the first conductive film 261 present in a region close to the light-emitting element 220 from the upper surface 241a of the wavelength conversion portion 241 to the end surface 242e of the enclosing portion 242 in a direction toward the light-emitting element 220, and thus, when the region on the side farther from the light-emitting element 220 is damaged, a current to the light-emitting element 220 can be reliably stopped. On the other hand, for example, in a case in which the unoccupied region is provided in the region of the upper surface 242a of the enclosing portion 242 on the side farther from the light-emitting element 220, even when the region of the upper surface 242a of the enclosing portion 242 on the side farther from the light-emitting element 220 is damaged, the current to the light-emitting element 220 may not be stopped. Thus, by providing the unoccupied region in the region, closer to the light-emitting element 220, of the upper surface 242a of the enclosing portion 242, the safety of the light-emitting device 200 can be further improved as compared to when the unoccupied region is provided in the region farther from the light-emitting element 220.

Because the light-emitting device 200 does not need indirect control using an external detection circuit, an increase in size and complicatedness of the entire device including the light-emitting device 200 can be suppressed. Further, there is also no risk that a safety measure does not function due to a failure of the external detection circuit itself. Furthermore, when the external detection circuit is provided and the control is indirectly performed, two processes of detecting an abnormality and executing the control based on the detection are performed, and thus a response speed of the safety measure to an occurrence of the abnormality is faster when a current circuit is directly stopped. The light-emitting device 200 has a mechanism for directly stopping current supply, but may further have a mechanism for indirectly stopping the current supply.

### Second Embodiment

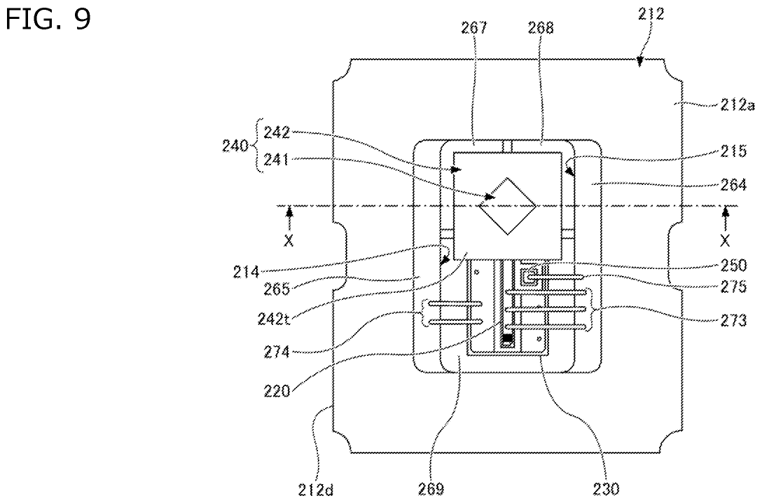

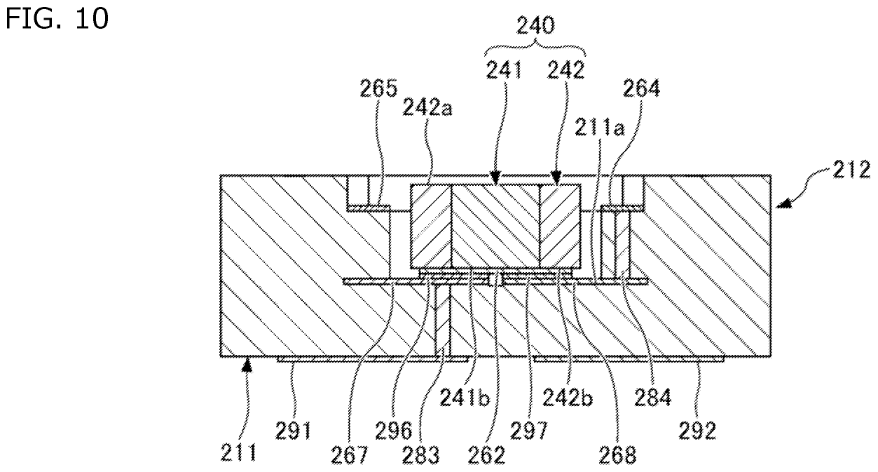

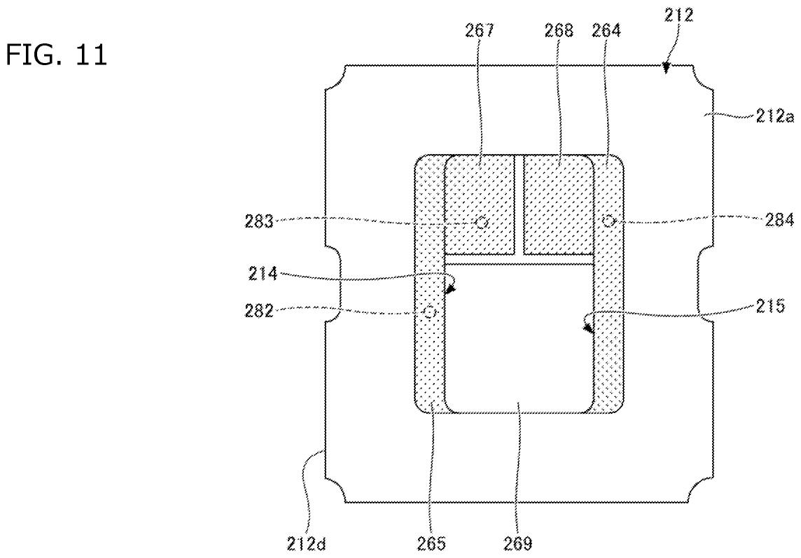

Next, a light-emitting device 201 according to a second embodiment will be described with reference to FIGS. 1 and 9 to 11. FIG. 1 is a schematic perspective view of the light-emitting device 201 according to the second embodiment. FIG. 9 is a schematic top view of the light-emitting device 201 illustrated in FIG. 1, from which a lid portion 213 is removed. FIG. 10 is a cross-sectional view of the light-emitting device 201 taken along a cross-sectional line X-X in FIG. 9. FIG. 11 is a schematic top view of the light-emitting device 201 illustrated in FIG. 9, from which members and wirings disposed on a placement surface 211a of a bottom portion 211 are removed. In FIG. 11, a part of a conductive film is illustrated in a dot pattern for the sake of description.

As illustrated in FIG. 1, the light-emitting device 201 according to the second embodiment has an outer shape same as or similar to that of the light-emitting device 200. However, the light-emitting device 201 differs from the light-emitting device 200 in a current path of a light-emitting element 220.

Specifically, in the light-emitting device 201, a wiring region of an enclosing portion 242 is not provided at an upper surface 242a of the enclosing portion 242, and is provided at a lower surface 242b of the enclosing portion 242. That is, in the light-emitting device 201, a conductive film corresponding to the first conductive film 261 illustrated in FIG. 8 is not provided at the upper surface 242a of the enclosing portion 242. On the other hand, as illustrated in FIG. 10, a second conductive film 262 being the wiring region is provided at the lower surface 242b of the enclosing portion 242. The second conductive film 262 may be provided only at the lower surface 242b of the enclosing portion 242, but may extend from the lower surface 242b of the enclosing portion 242 to a lower surface 241b of a wavelength conversion portion 241 as illustrated in FIG. 10.

Further, a wavelength conversion member 240 may be provided at the placement surface 211a of the bottom portion 211 without a submount 235 interposed therebetween. When the wavelength conversion member 240 is provided at an upper surface of the placement surface 211a without the submount 235 interposed therebetween, a height of the light-emitting device 201 can be reduced.

Furthermore, the enclosing portion 242 of the wavelength conversion member 240 may be formed by using a conductive material such as aluminum. In that case, the lower surface 242b of the enclosing portion 242 can be used as the wiring region without providing the conductive film on the lower surface 242b of the enclosing portion 242.

A seventh conductive film 267 and an eighth conductive film 268 are provided in a region of the placement surface 211a of the bottom portion 211 at which the submount 230 is not disposed in the top view. When the submount 230 is not used, the seventh conductive film 267 and the eighth conductive film 268 can be provided in a region of the placement surface 211a of the bottom portion 211 at which the light-emitting element 220 is not disposed in the top view. At least a part of the seventh conductive film 267 and the eighth conductive film 268 overlaps the wavelength conversion member 240 in the top view. Further, the seventh conductive film 267 and the eighth conductive film 268 are bonded to the second conductive film 262. The seventh conductive film 267 and the eighth conductive film 268 are separated from each other.

As illustrated in FIG. 10, the second conductive film 262 has a region overlapping the seventh conductive film 267 and the eighth conductive film 268 in the top view. Then, the seventh conductive film 267 is electrically connected to the second conductive film 262 via a second bonding portion 296 having conductivity. The eighth conductive film 268 is electrically connected to the second conductive film 262 via a third bonding portion 297 having conductivity. In other words, the seventh conductive film 267, the second bonding portion 296, the second conductive film 262, the third bonding portion 297, and the eighth conductive film 268 are connected in series.

For example, a metal film can be used as the second conductive film 262, the seventh conductive film 267, and the eighth conductive film 268. Examples of the metal film include Ni/Au (metal film layered in the order of Ni, Au), Ti/Pt/Au (metal film layered in the order of Ti, Pt, Au), and the like. A film such as indium tin oxide (ITO) other than the metal film may be used as the second conductive film 262, the seventh conductive film 267, and the eighth conductive film 268. Examples of the second bonding portion 296 and the third bonding portion 297 include AuSn, a conductive paste, a metal bump, and the like.

The seventh conductive film 267 is electrically connected to a first external connection electrode 291, provided at a lower surface 211b of the bottom portion 211, via a third via wiring 283 passing through the bottom portion 211. The eighth conductive film 268 is electrically connected to a fourth conductive film 264, provided at an upper surface 215a of a second stepped portion 215, via a fourth via wiring 284 passing through the second stepped portion 215.

In the light-emitting device 201, a current path of the fourth conductive film 264, a third wiring 273, a first electrode 221, a second electrode of the light-emitting element 220, a fourth wiring 274, a fifth conductive film 265, a second via wiring 282, and a second external connection electrode 292 is the same as or similar to that of the light-emitting device 200. In the light-emitting device 201, the fifth conductive film 265 may be provided at an entire surface of an upper surface 214a of a first stepped portion 214, or may be provided in a shape same as or similar to that of the light-emitting device 200.

In other words, in the light-emitting device 201, the current path of the light-emitting element 220 includes the first external connection electrode 291, the third via wiring 283, the seventh conductive film 267, the second bonding portion 296, the second conductive film 262, the third bonding portion 297, the eighth conductive film 268, the fourth via wiring 284, the fourth conductive film 264, the third wiring 273, the first electrode 221, the second electrode of the light-emitting element 220, the fourth wiring 274, the fifth conductive film 265, the second via wiring 282, and the second external connection electrode 292.

In this way, in the light-emitting device 201, the current path of the light-emitting element 220 is configured so as to include the second conductive film 262 provided at the lower surface 242b of the enclosing portion 242 of the wavelength conversion member 240. Thus, when a crack, detachment, and the like occur in the wavelength conversion member 240, and the second conductive film 262 is disconnected, or the second bonding portion 296 and/or the third bonding portion 297 is disconnected, a current can be prevented from flowing through the light-emitting element 220. Further, because a wiring is not bonded to an upper surface 241a of the wavelength conversion portion 241, a size of the wavelength conversion member 240 can be reduced.

### Third Embodiment

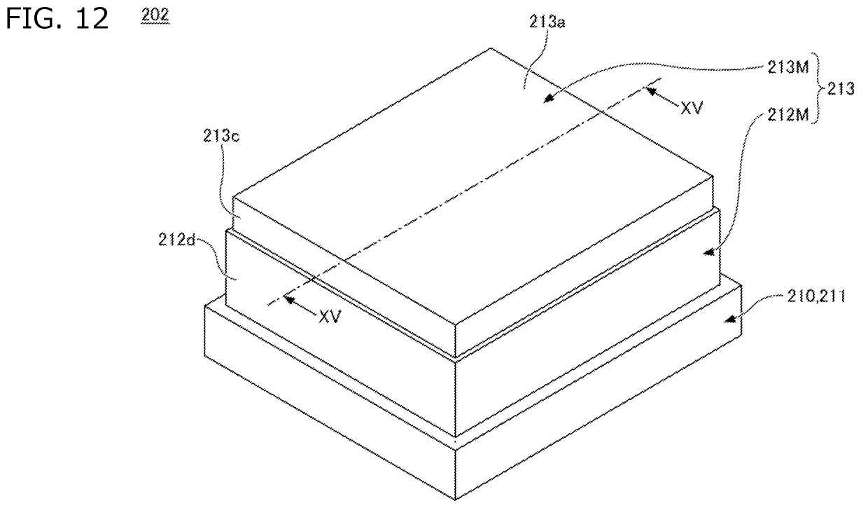

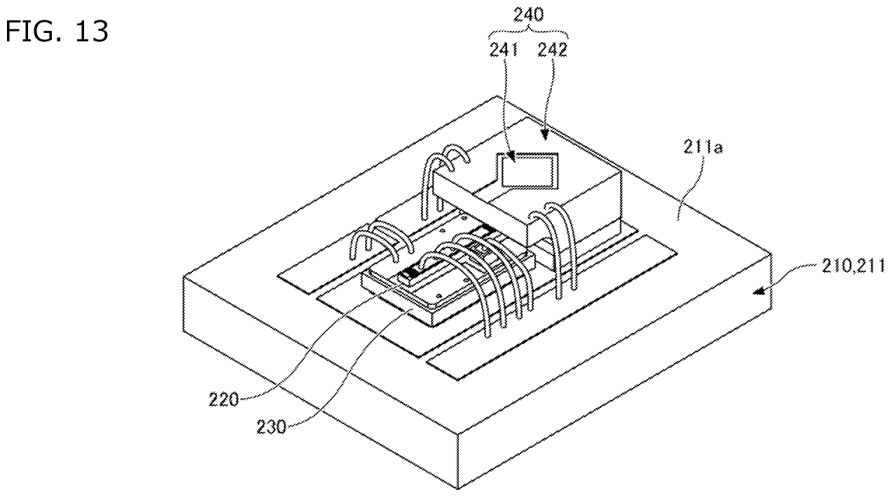

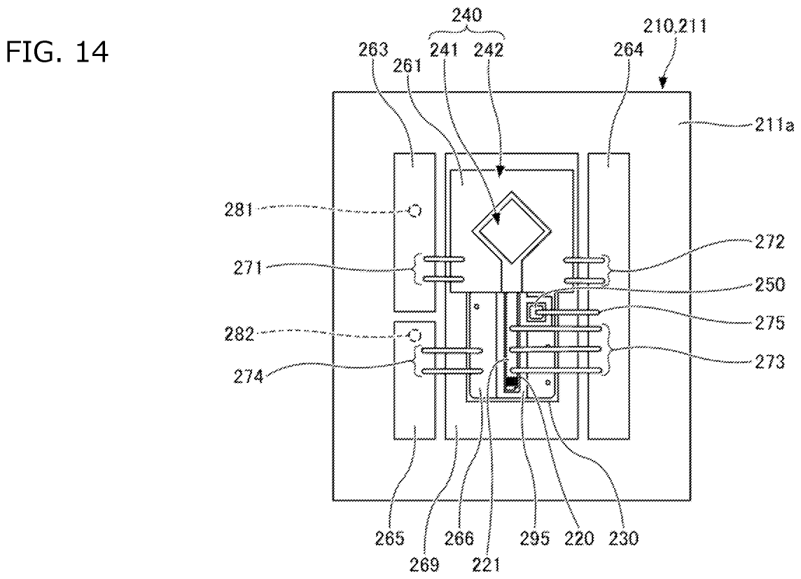

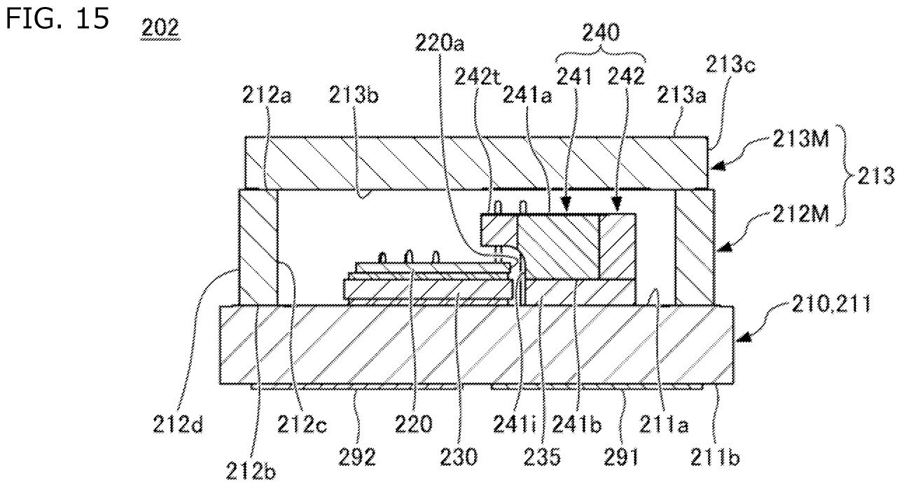

Next, a light-emitting device 202 according to a third embodiment will be described with reference to FIGS. 12 to 15. FIG. 12 is a schematic perspective view exemplifying the light-emitting device 202 according to the third embodiment. FIG. 13 is a schematic perspective view of the light-emitting device 202 illustrated in FIG. 12, from which a lid portion 213 is removed. FIG. 14 is a schematic top view of the light-emitting device 202 illustrated in FIG. 13. FIG. 15 is a cross-sectional view of the light-emitting device 202 taken along a cross-sectional line XV-XV in FIG. 12.

The light-emitting device 202 according to the third embodiment differs from the light-emitting device 200 illustrated in FIG. 1 and the like in that a base member 210 is formed by only a bottom portion 211, and the lid portion 213 is formed by a flat plate portion 213M and a frame portion 212M. For example, the frame portion 212M has a rectangular frame-like shape in the top view. For example, the flat plate portion 213M has a rectangular shape in the top view. One or a plurality of inner lateral surfaces 212c of the frame portion 212M do not have a stepped portion. The lid portion 213 may be monolithically formed, or may be obtained by individually forming the frame portion 212M and the flat plate portion 213M and bonding them together. For example, an inorganic material such as glass and ceramic can be used as a main material of the lid portion 213. The frame portion 212M and the flat plate portion 213M may be formed of a different material. In that case, an inorganic material such as glass and ceramic and the like may be used. The lid portion 213 is bonded to an outer edge of a placement surface 211a of the bottom portion 211. For example, a metal adhesive may be used for bonding of the bottom portion 211 and the lid portion 213. Examples of the metal adhesive include AuSn and a metal paste. A resin adhesive may be used for bonding of the bottom portion 211 and the lid portion 213.

In the example in FIG. 14, the placement surface 211a of the bottom portion 211 has a rectangular shape with an optical axis direction of a light-emitting element 220 as a longitudinal direction in the top view. A third conductive film 263, a fourth conductive film 264, a fifth conductive film 265, and a metal film 269 are provided at the placement surface 211a of the bottom portion 211. The third conductive film 263 and the fifth conductive film 265 are disposed at one side of the metal film 269 in a direction perpendicular to the longitudinal direction while being separated from the metal film 269. The third conductive film 263 and the fifth conductive film 265 are separated from each other. The fourth conductive film 264 is disposed at the other side of the metal film 269 in the direction perpendicular to the longitudinal direction while being separated from the metal film 269. The third conductive film 263 and the fifth conductive film 265 substantially face the fourth conductive film 264 with the metal film 269 interposed therebetween.

In the light-emitting device 202 as in the case of the light-emitting device 200, the third conductive film 263 is electrically connected to a first conductive film 261, being a wiring region provided at an upper surface 242a of an enclosing portion 242, via a first wiring 271. The first conductive film 261 is electrically connected to the fourth conductive film 264 via a second wiring 272. The fourth conductive film 264 is electrically connected to the first electrode 221 of the light-emitting element 220 via a third wiring 273. A second electrode of the light-emitting element 220 is electrically connected to the fifth conductive film 265 via a fourth wiring 274.

The third conductive film 263 is electrically connected to a first external connection electrode 291, provided at a lower surface 211b of the bottom portion 211, via a first via wiring 281 passing through the bottom portion 211. Further, the fifth conductive film 265 is electrically connected to a second external connection electrode 292, provided at the lower surface 211b of the bottom portion 211, via a second via wiring 282 passing through the bottom portion 211. That is, a current path of the light-emitting element 220 includes the first external connection electrode 291, the first via wiring 281, the third conductive film 263, the first wiring 271, the first conductive film 261 being the wiring region, the second wiring 272, the fourth conductive film 264, the third wiring 273, the first electrode 221, the second electrode of the light-emitting element 220, the fourth wiring 274, the fifth conductive film 265, the second via wiring 282, and the second external connection electrode 292.

In this way, the current path of the light-emitting element 220 in the light-emitting device 202 can be the same as the current path of the light-emitting element 220 in the light-emitting device 200. As a result, safety same as or similar to that of the light-emitting device 200 can be secured in the light-emitting device 202.

For example, the light-emitting devices 200, 201, and 202 can be used for an on-vehicle headlight. Further, the applications of the light-emitting devices 200, 201, and 202 are not limited thereto, and those can be used for lighting, a projector, a head-mounted display, and a light source such as a backlight of other displays.

Although the preferred embodiments and the like have been described in detail above, the disclosure is not limited to the above-described embodiments and the like, various modifications and substitutions can be made to the above-described embodiments and the like without departing from the scope described in the claims.

The wavelength conversion member 240 is one example of a light conversion portion that converts light emitted from the light-emitting element 220. The light emitted from the light-emitting element 220 is incident on the light conversion portion, and the light conversion portion converts the light by wavelength conversion, diffusion, or other optical action and emits the light. The light incident on the light conversion portion has different optical properties before and after the conversion by the light conversion portion. The light emitted from the light-emitting device is desired to be light after being converted by the light conversion portion, but is not desired to be light before being converted. The wavelength conversion member 240 is not limited to such a light conversion portion, but it can be said to be a corresponding example of such a light conversion portion.

What is claimed is:

1. A light-emitting device comprising:
a base member having a placement surface;
a light-emitting element disposed on the placement surface, and configured to emit first light from an emitting end surface; and
a wavelength conversion member disposed at a portion of the placement surface to which the light emitted from the first light-emitting element travels, the wavelength conversion member having
a wiring region being a part of a current path electrically connected to the light-emitting element,
a wavelength conversion portion having an incident lateral surface on which the first light emitted from the light-emitting element is incident, and an upper surface from which second light is emitted, and
an enclosing portion surrounding the wavelength conversion portion in a top view and provided with the wiring region.

2. The light-emitting device according to claim 1, wherein
the second light includes the first light.

3. The light-emitting device according to claim 1, wherein
the enclosing portion has an upper surface surrounding the upper surface of the wavelength conversion portion in the top view, and
the wiring region is a first conductive film provided at the upper surface of the enclosing portion.

4. The light-emitting device according to claim 1, wherein
the enclosing portion has a lower surface facing the placement surface of the base member, and
the wiring region is a second conductive film provided at the lower surface of the enclosing portion.

5. The light-emitting device according to claim 1, wherein
the enclosing portion is formed of a conductive material.

6. The light-emitting device according to claim 1, wherein
the base member includes a bottom portion defining the placement surface, and a frame portion surrounding the placement surface in the top view, and
the wavelength conversion member and the light-emitting element are disposed inward of the frame portion in the top view.

7. The light-emitting device according to claim 6, further comprising
a lid portion bonded to the frame portion, and forming a sealed space where the light-emitting element and the wavelength conversion member are disposed.

8. The light-emitting device according to claim 1, wherein
a lateral surface of the wavelength conversion member has a recessed portion, and
the recessed portion is partially defined by the wavelength conversion portion.

9. The light-emitting device according to claim 8, wherein
the emitting end surface of the light-emitting element overlaps the recessed portion in the top view.

10. The light-emitting device according to claim 1, wherein
the base member has a bottom portion and a frame portion,
the wavelength conversion member and the light-emitting element are disposed inward of the frame portion in the top view,
the light-emitting device further includes
a first stepped portion having an upper surface located above an upper surface of the bottom portion and below an upper surface of the frame portion; and
a third conductive film disposed on the upper surface of the first stepped portion,
the third conductive film is electrically connected to the wiring region via a first wiring, and
the current path is formed at least through the third conductive film, the first wiring, and the wiring region.

11. The light-emitting device according to claim 10, further comprising
a second stepped portion having an upper surface located above the upper surface of the bottom portion and below the upper surface of the frame portion; and
a fourth conductive film disposed on the upper surface of the second stepped portion, wherein
the wiring region is electrically connected to the fourth conductive film via a second wiring, and
the current path is formed at least through the third conductive film, the first wiring, the wiring region, the second wiring, and the fourth conductive film.

12. The light-emitting device according to claim 11, further comprising
a third wiring electrically connecting the fourth conductive film to a first electrode of the light-emitting element, wherein
the current path is formed at least through the third conductive film, the first wiring, the wiring region, the second wiring, the fourth conductive film, the third wiring, and the first electrode.

13. The light-emitting device according to claim 12, further comprising
a fifth conductive film disposed on the first stepped portion while being spaced apart from the third conductive film; and
a fourth wiring electrically connecting a second electrode of the light-emitting element electrically connected to the fifth conductive film, wherein
the current path is formed at least through the third conductive film, the first wiring, the wiring region, the second wiring, the fourth conductive film, the third wiring, the first electrode, the second electrode, the fourth wiring, and the fifth conductive film.

14. The light-emitting device according to claim 13, further comprising
a lid portion bonded to the frame portion, and forming a sealed space where the light-emitting element and the wavelength conversion member are disposed, wherein
the third conductive film, the first wiring, the wiring region, the second wiring, the fourth conductive film, the third wiring, the first electrode, the second electrode, the fourth wiring, and the fifth conductive film are present in the sealed space.

15. The light-emitting device according to claim 14, wherein
the third conductive film is electrically connected to, via a first via wiring passing through the first stepped portion, a first external connection electrode disposed on a lower surface of the base member,
the fifth conductive film is electrically connected to, via a second via wiring passing through the first stepped portion, a second external connection electrode disposed on the lower surface of the base member, and
the current path is formed at least through the first external connection electrode, the first via wiring, the third conductive film, the first wiring, the wiring region, the second wiring, the fourth conductive film, the third wiring, the first electrode, the second electrode, the fourth wiring, the fifth conductive film, the second via wiring, and the second external connection electrode.

16. A light-emitting device comprising:
a base member having a placement surface;
a light-emitting element disposed on the placement surface, and configured to emit first light from an emitting end surface; and
a light conversion member disposed at a portion of the placement surface to which the first light emitted from the light-emitting element travels, the light conversion member having
a wiring region being a part of a current path electrically connected to the light-emitting element,
a light conversion portion having an incident lateral surface on which the first light emitted from the light-emitting element is incident, and an upper surface from which second light is emitted, and
an enclosing portion surrounding the light conversion portion in a top view and provided with the wiring region.
